(19) United States
(12) Patent Application Publication
(10) Pub. No.: US 2025/0006614 A1
(43) Pub. Date: Jan. 2, 2025

(54) INTERVENING LAYERS FOR THRU-VIA SEED METALLIZATION

(71) Applicants: Rengarajan Shanmugam, Chandler, AZ (US); Darko Grujicic, Chandler, AZ (US); Suddhasattwa Nad, Chandler, AZ (US); Srinivas Venkata Ramanuja Pietambaram, Chandler, AZ (US); Brian Balch, Chandler, AZ (US); Xing Sun, Beijing (CN); Qiang Li, Chandler, AZ (US); Jason Scott Steill, Phoenix, AZ (US); Micah David Armstrong, Scottsdale, AZ (US); Marcel Arlan Wall, Phoenix, AZ (US)

(72) Inventors: Rengarajan Shanmugam, Chandler, AZ (US); Darko Grujicic, Chandler, AZ (US); Suddhasattwa Nad, Chandler, AZ (US); Srinivas Venkata Ramanuja Pietambaram, Chandler, AZ (US); Brian Balch, Chandler, AZ (US); Xing Sun, Beijing (CN); Qiang Li, Chandler, AZ (US); Jason Scott Steill, Phoenix, AZ (US); Micah David Armstrong, Scottsdale, AZ (US); Marcel Arlan Wall, Phoenix, AZ (US)

(21) Appl. No.: 18/216,738

(22) Filed: Jun. 30, 2023

(51) Int. Cl. H01L 23/498; H01L 21/48; H01L 23/15

(52) U.S. Cl. CPC H01L 23/49827; H01L 21/486; H01L 23/15

(57) ABSTRACT

A semiconductor substrate that includes a glass layer with a first and second major surface, at least one electrical transmission through hole extending from the first major surface to the second major surface and an intervening layer coupled with at least one of the first major surface, the second major surface and the electrical transmission through hole. The intervening layer includes a metal, silicon and oxygen. A metal layer is bonded with the intervening layer.

### TECHNICAL FIELD

This document pertains generally, but not by way of limitation, to electrical devices with layers having at least one intervening layer provided at least partially within an electrical transmission through hole of, for example, a semiconductor substrate. By way of example, the electrical transmission through hole includes a metal layer coupled with at least one intervening layer within the electrical transmission through hole.

### BACKGROUND

Computer chips, and other similar components for electronic systems can be formed from layers of materials that are stacked or placed one on top of the other. The architecture of computer chips, substrates, packages or layers can include through holes, or through vias, that provide an electrical transmission pathway from one part of the architecture to another, such as between or within layers, substrates, dies or the like.

The through holes usually have an exposed metallic surface coupled to the inner surface of the through hole and, optionally, coupled to surfaces surrounding the through hole. The metallic surface can provide a lower resistance and enhance conductivity for the electrical transmission between components of a computer chip. The metallic surfaces can be coupled, adhered, fixed or the like to the surfaces of the chip where electrical transmissions occur. In an example, copper is plated on the interior surfaces of the through hole to provide a lower resistance and also enhance electrical conductivity through an electrical transmission pathway. The metallic surfaces within and on a chip need to be stable and relatively static so the electrical pathways are not damaged, deformed or the like. Damaged or deformed through holes can result in upstream failures with the chip and its components.

Some layers of an electrical system, such as a semiconductor substrate or layers of a semiconductor substrate, assists in promoting a strong bond between layers in a through hole to minimize any occurrences of malfunctioning electrical connections. For example, an intervening layer, such as an adhesion layer, is an example of an intermediary layer used to help promote coupling of a conductive metal such as copper seed to surfaces of a semiconductor substrate, layer or core. A layer of titanium can be used as an adhesion layer that is deposited within a through hole or on a surface of a substrate, layer or core. The metal, such as titanium, is deposited on the desired surfaces with, for example, physical vapor deposition. However, to couple, adhere or bind the intervening layer to a specified surface can require a longer physical vapor deposition (PVD) process or more than just PVD because of the differences in materials between the surface and the adhesion layer. For example, titanium deposition is subjected to high thermal loading in a PVD process to form the chemical bond between the titanium and core or layer. The titanium, as a material used in an intervening layer, is then chemically bonded with the metal layer, such as copper via PVD, sputtering or the like.

The distinct layers can be weak points in the architecture of the chip. For example, a strong coupling (adhesion, bond or the like) may not have occurred during the PVD. A lack of a strong bond can form a weak point where delamination can occur during manufacture or use.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is an illustration of a cross section of an example process of forming a layer of an electronic system.

FIG. 2 is an illustration of a cross section of process of forming a layer of an electronic system

FIG. 3 is an illustration of a cross section of a process of forming a layer of an electronic system.

FIG. 4 is an illustration of an electronic system coupled with a die.

FIG. 5 is an illustration of a system level diagram, depicting an example of an electronic system.

### DETAILED DESCRIPTION

Some substrates used for computer chips or other electrical systems can be built, formed or otherwise assembled from layers of materials, for example resins, polymers, glass or the like. The foundation of these layers can be a core layer on which subsequent layers or other components of a chip can be coupled, stacked, built up, or assembled.

A layer can have a dielectric material, as a layer, or another polymer-based material layer coupled to upper or lower surfaces of a preceding or subsequent layer. Electrical, mechanical or electro-mechanical components can be coupled to a surface of a layer. In an example, layers are coupled to the core to form stacked layers with electrically conductive interconnects applied, coupled or formed on or to surfaces of at least one layer of a stack of layers.

In some examples, polymers are difficult to couple together in a secured and stable manner. Polymers, as a layer material, or dielectric materials coupled to the resin layers, in some situations, are a deformable material. Polymers layers can also deform when subjected to applied pressures or when the material is subjected to fluctuations in temperature. Deformations such as expansion, contraction, compression or the like, in some examples, results in changes to locations of components or architecture, such as through holes. Deformations such as applied pressures or temperature fluctuations are examples of environmental conditions that can occur during manufacturing of computer chips. These types of deformations can also result in changes to components of a layer, substrate or the like. In an example, though holes, through glass vias, electrical transmission pathways, or the like are components that can be subjected to deformations or mechanical displacements.

In an example, a layer or a core (hereinafter layer refers to refer to a core or other structural support component such as for a die) is formed from glass. The present inventors have recognized that glass is a stable structure (e.g., nondeformable, fixed, rigid or the like) that can be used for layers within a substrate, core or computer chip. Glass, for example, when subjected to changes in environmental conditions, does not usually experience significant changes to material properties. Glass, in its solid state, is generally known as a non-pliable material. Glass can also be a material that is not easily deformed when subjected to changes in environmental conditions. For example, when glass is exposed to pressures it does not easily change in structure or form. When glass is exposed to pressures it usually is not compressed or expanded in thickness, or a depth direction. In an example, glass does not easily expand in a lateral or longitudinal direction when subjected to pressure or stresses are applied to the surface.

The thermal mechanical benefits of glass materials can be advantageous for architectural aspects of chips, and components of the chips. Such thermal mechanical benefits can minimize undulations that can occur when layers are compressed or stacked on previous layers. In other words, the thermal mechanical qualities of glass can result in the glass retaining substantially an original shape, dimension, profile or the like. The thermal mechanical quantities of glass can also result in minimization of the occurrence of shrinkage or expansion when further layers are stacked. The thermal mechanical qualities of glass can also be advantageous when adding conductive materials, such as copper, to the surface of the glass.

In an example, glass is a material with low conductivity. Glass, in another example, is a material that minimizes migration of conductive materials across surfaces. During manufacturing of the core or the chip, conductive materials, such as copper, are known to migrate across surfaces and can damage or coat other components of the core or chip. In some instances, when migration occurs, affected components are known to not function efficiently or effectively.

The stable structure of glass can assist with maintaining the placement, orientation or the like of components, such as additional layers, though holes, conductive materials or the like during manufacturing, assembly or use. In an example, other glass layers or other material layers (e.g., dielectric, polymer, adhesion, metallic, or the like) can be stacked on the glass layer. The glass layer, for example, can be a central core for a substrate or chip, or the glass layer can be an individual core that is not central, but instead at a different location within the layers of the substrate or chip.

The glass layer can include a silicate-based glass (e.g., lithium-silicate, borosilicate, aluminum silicate, etc.). In variations, the glass of the glass layer can be a lower quality glass (e.g., glass made with soda lime), or a higher quality glass (e.g., glass made with fused silica). Glass, as a silicate, is any member of a family of polyatomic anions consisting of silicon and oxygen. In an example, the oxygen within glass can promote bonding with other materials, such as other elemental metals, or metal alloys. Chemical bonding, such as between oxygen and metals, can form a stronger adhesion force between the surface of the glass layer and other subsequent layers.

In an example, physical vapor deposition (PVD) is a process that can be used to deposit metals on a glass layer. PVD is an example process that can be used to deposit vaporized solid materials onto the surface of another material, such as glass. Sputtering (a subset of PVD), Chemical vapor deposition (CVD), Atomic layer deposition (ALD) are different methods to deposit metal and adhesion layers onto substrates. These methods can be utilized to promote chemical bonding between the oxygen in glass and any metal.

In an example, coupling a glass layer with subsequent layer requires an intervening layer. For example, the intervening layer is an intermediary layer disposed between a surface of the glass layer and a surface of a subsequent metal layer, or another subsequent layer formed from a different material. Optionally, the intervening layer is an adhesion layer. The intervening layer, or adhesion layer, couples, binds, or otherwise joins the glass layer (e.g., a surface of the glass layer) with a subsequent layer (e.g., another glass layer, dielectric layer, conductive layer, metal layer or the like). For example, a conductive material, such as copper, requires an intermediary layer, such as an adhesion layer, to achieve coupling with the glass layer. For example, a surface of the glass layer is coupled (e.g, bonded, adhered, joined, connected, or the like) with one side of a titanium layer and the opposing side of the titanium layer is bonded with a copper layer (e.g., seed copper). In another example, the titanium layer can be deposited on the surface of glass with PVD and copper can be deposited on the titanium with PVD, or any other method suitable for the purpose.

In some examples, conductive materials, such as copper, can migrate across or along surfaces during manufacturing processes associated with the glass layer, core, or chip. Glass is a material that can minimize migration of conductive materials across along surfaces because of its low conductivity. Migration can damage or coat other components of the layer, core or chip. When migration occurs, affected components are known, in some instances, to not function efficiently or effectively. In an example, copper deposited on a surface can migrate to unwanted or undesired locations of the surface, and beyond the adhesive material. The copper, in another example, can migrate from a surface within a through hole to a first surface or second surface of the layer, core or the like.

The glass layer can be coupled with another one or more other layers, such as another glass layer. In an example with a first glass layer coupled with a second layer, the components on each of first glass layer and the second layer are aligned. For example, a through hole in the first glass layer provides an electrical pathway from the first glass layer to the second layer. The electrical pathway (through hole) can have an electrically conductive material coupled to at least part of an inner surface of the electrical pathway. The electrically conductive material, such as copper, can be coupled (e.g., affixed, connected, deposited or the like) on the inner surface of the electrical pathway with an adhesive material, such as an intervening layer. For example, a titanium metal layer is used as the intervening layer for through holes and build-up metallization for the glass layer-based substrate packaging for integrated circuits.

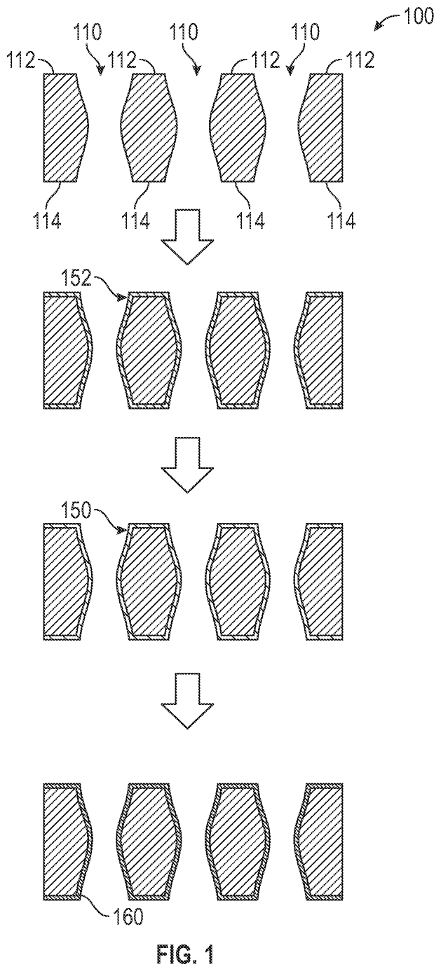

Illustrated in FIG. 1 is an example of part of a semiconductor substrate that includes a glass layer 100 with at least one electrical transmission through hole 110. The glass layer 100 can be a glass core or an individual layer of a plurality of layers in a substrate. In the example illustrated in FIG. 1, the glass layer 100 has a first major surface 112 and a second major surface 114. The first major surface 112 and the second major surface 114 can each be exposed surfaces. In an example, the first major surface 112 and the second major surface 114 are exposed during manufacturing of the semiconductor substrate, but not exposed when a completed semiconductor substrate is formed. In another example, one of the first major surface 112 and the second major surface 114 is exposed with the glass layer 100 as the final (top or bottom) layer of a semiconductor substrate. The first major surface 112 is on an opposing side of the glass layer 100 from the second major surface 114. Electrical components can be coupled to either or both of the first major surface 112 and the second major surface 114. An electrical transmission through hole 110, as an example of an architectural component, extending between the first major surface 112 and the second major surface 114.

The electrical transmission through hole 110 can have a conductive material layer 160 coupled to at least the inner surface 122 of the electrical transmission through hole 110. The conductive material layer 160 can be a metal layer that has electrically conductive properties suitable for the specified purpose. For example, the conductive material layer 160 is at least one of copper, cobalt, ruthenium, rhodium, aluminum, gold, silver, palladium or the like. As illustrated in FIG. 1, the conductive material layer 160 can be coupled to at least one of the first major surface 112 and the second major surface 114.

The conductive material layer 160, or metal layer, can be coupled with an inner surface 122 of the electrical transmission through hole 110 with, for example, an intervening layer 150. The intervening layer 150 can include a deposition of an atomized metal 152, such as titanium. For example, an atomized metal 152 couples (e.g., binds, adheres, joins, connects or the like) with the oxygen and silicon from the glass layer to form the intervening layer 150. Stated another way, the intervening layer 150 illustrated in the example of FIG. 1, can be formed from chemical bonds between an atomized metal and the surfaces 112, 114, 122 of the glass layer 100. For example, titanium can chemically bond with the glass to form a —Si—O—Ti bond.

The atomized metal 152 can be deposited on any of the surfaces 112, 114, 122 of the glass layer 100 with PVD, CVD, ALD or the like. After the atomized metal 152 is deposited on the surfaces 112, 114, 122, the atomized metal 152 can be subjected to an anneal process. In another example, the anneal process is performed in an inert environment. For example, the anneal process is performed in a system with an inert gas to ensure only the intervening layer and the glass substrate react with each other. In such an example, the metal in a metal-silicon-oxygen alloy, such as a metal silicate, reacts with the glass in the glass layer to form a bond between the two layers.

In an example, an intervening layer includes metal, silicon and oxygen. Optionally, the intervening layer includes a metal silicate. In some examples, when the metal reacts with the glass there is a gradient of silicon in the metal, silicon, oxygen combination or alloy. In such a situation when the silicon from the glass diffuses into the metal layer, a gradient of silicon can form such that there is a higher silicon concentration at the interface between the metal and the glass, and a lower concentration at an inner surface of the intervening layer. An annealing process can provide thermal energy to accelerate the kinetics of chemical bonding reactions between the intervening layer 150 and glass layer 100 in addition to modulating the microstructural properties of metal and intervening layers.

In an example the metal of the intervening layer includes titanium. In this example, glass layer 110 receives a deposition of titanium through processes such as PVD, CVD, ALD or the like. Either concurrently, or subsequently an inert anneal process is performed on the glass layer 100 with the titanium deposition. The titanium can then form a TiₓSi₁₋ₓO₂ layer as the intervening layer. In an example, the enhanced intervening can allow for a thinner intervening layer and a shorter deposition process. A shorter deposition process can lead to a more efficient manufacturing process that is at least partially due to a thinner deposition of the intervening layer 150.

A thin intervening layer can be a few nanometers thick to tens of nanometers thick. In an example, the thin intervening layer can be between 1 nanometer and 40 nanometers. In an example, the thin intervening layer can be between 5 nanometers and 30 nanometers. A titanium film as the intervening layer 150 (for example TiₓSi₁₋ₓO₂) can be more securely coupled (adhered, bound, fixed or the like) to the surfaces 112, 114, 122 of the glass film because of the co-reaction of the deposition of titanium with the glass and the formation of TiₓSi₁₋ₓO₂.

The electrically conductive material 160 is coupled with the surfaces 112, 114, 122 of the glass layer 100 via the intervening layer 150. Copper, as the metal layer 160, can be bonded to the intervening layer 150. In an example, the copper is more securely coupled to the glass layer 100 because the intervening layer 150 is chemically coupled with the glass layer 100.

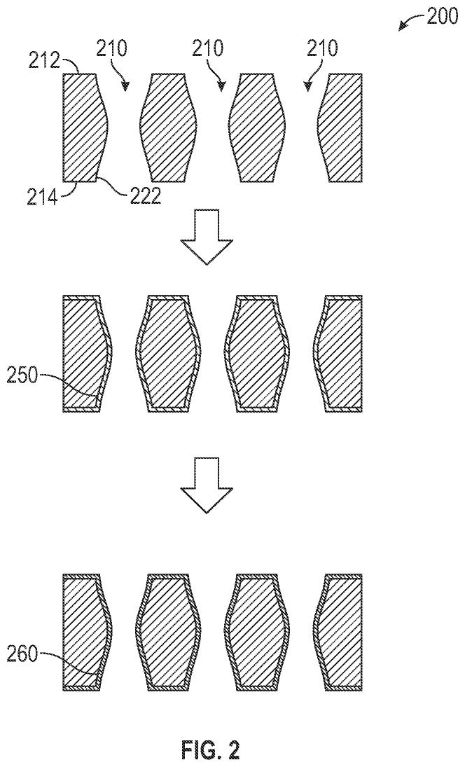

Illustrated in FIG. 2 is an example of a layer 200 similar to the glass layer 100. The layer 200 can be a semiconductor substrate layer that is a glass layer. The layer 200 can have at least one through hole 210 extending between a first surface 212 and a second surface 214. The at least one through hole 210 can be an electrically conductive through hole. The through hole 210 has, for example, an intervening layer 250, such as an adhesion layer or similar layer that is coupled to an inner surface 222. The intervening layer 250 (e.g., adhesion layer) can be coupled to the first surface 212 or the second surface 214 of the layer 200.

The intervening layer 250 (e.g., adhesion layer), in the example illustrated in FIG. 2, is coupled, for example, by chemically bonding the intervening layer 250 with the layer 200, such as on a surface such as the through hole 210, the first surface 212, and the second surface 214. In an example, TiₓSi₁₋ₓO₂ is a metal/metal oxide deposited on at least one surface 212, 214, 222 as the intervening layer 250. The intervening layer 250 can be deposited with any method suitable for the purpose such as PVD, CVD, ALD or the like. In an example, a co-sputter technique can deposit a metal oxides, or stoichiometric metal alloys of a specified composition can be deposited directly on the layer 200. In another example, co-sputtering uses two or more targets to achieve a desired stoichiometry. One variant of co-sputtering can also make use of TiO₂ and SiO₂ targets in a radio frequency (RF) or direct current (DC) sputter configuration. In another configuration, cold sputtering is used to deposit the intervening layer 250 (e.g., adhesion layer or the like) on at least one of the surfaces 212, 214, 222. For example, titanium is the metal in a metal-silicon-oxygen alloy forming, for example titanium silicate. The titanium silicate, as the intervening layer 250, can also be deposited by sputtering or co-sputtering onto selected surfaces, such as one of the first surface 212, the second surface 214, or the inner surface 222 of the through hole 210 of the layer 200. Co-sputtering can “drive” the titanium silicate into the selected surface. Sputtering or co-sputtering can form an intervening layer 250 (e.g., adhesion layer or the like) that is thinner than bonding an intervening layer with other known methods. Sputtered layers, such as the intervening layer 250, can be physically detectable. In an example, the intervening layer 250 can be substantially amorphous, or have some level of crystallinity, and detectable with an electron microscope or the like.

The intervening layer 250, in an example, a PVD, ALD or CVD process deposits the intervening layer 250 with a thickness between 5 and 30 nanometers thick. In another example, the intervening layer 250 is fewer than 5 nanometers thick or greater than 30 nanometers thick. In another example, the intervening layer is between 5 nanometers and 20 nanometers thick. The intervening layer 250, of a specified thickness, can be used to couple a metal layer 260 with at least one of the surfaces 212, 214, 222.

As illustrated in the example of FIG. 2, the metal layer 260 is deposited on the first surface 212, the second surface 214 and the inner surface 222 of the at least one through hole 210. In an example, the metal layer 260 is copper. One side of the copper layer, as the metal layer 260, can be coupled to at least one of the surfaces 212, 214, 222 with the intervening layer 250 (e.g., adhesion layer or the like) that has been co-sputtered on the desired surface and the other side of the copper layer can be exposed. The exposed side of the copper layer can be an electrically conductive pathway, for example from the first surface 212 through the through hole 210 to the second major surface 214. In an example, the final layer 200 includes at least the layer 200 formed from glass, a titanium-silicon-oxygen alloy as the intervening layer 250 and a metal layer 260. The metal layer 260 is coupled with the intervening layer 250. As illustrated in FIG. 2, the intervening layer 250 and the metal layer 260 are disposed on the first major surface 212, the second major surface 214 and the inner surface 222 of the through hole 210.

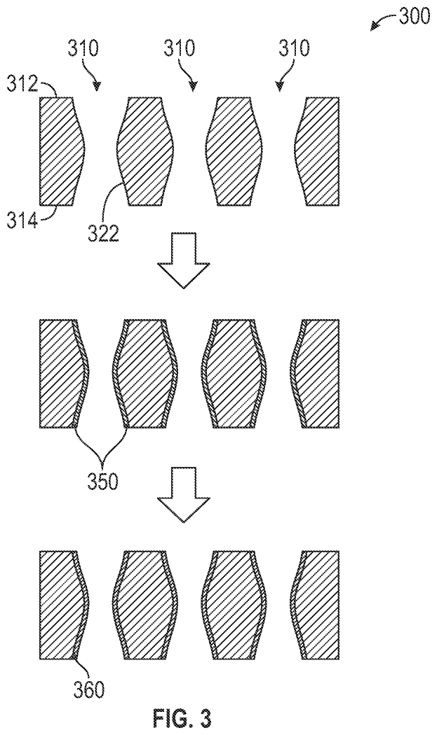

Illustrated in FIG. 3 is another example of a semiconductor substrate layer that is, for example, a glass layer 300 with a plurality of through holes 310. The glass layer 300 can have a plurality of through holes 310 that extend between a first major surface 312 to a second major surface 314. Each of the plurality of though holes 310 has an inner surface 322 that can provide an electrically conductive pathway between the first major surface 312 and the second major surface 314.

In the example illustrated in FIG. 3, a silicon layer 350 is deposited on the inner surface 322 of at least one of the plurality of through holes 310. The silicon layer 350 can be deposited within the through hole 310 proximate to the first major surface 312 and the second major surface 314. When the silicon layer 350 is deposited on the inner surface 322 with CVD or ALD, it is coupled (e.g., bonded, adhered, or the like) with the inner surface 322 to provide a stable intervening layer. In an example, a pristine and thin silicon layer 350 is deposited onto the glass layer 300 within the through hole 310. The silicon layer 350 can be a thin layer of silicon deposited by a process such as CVD or ALD with a thickness of, for example, fewer than 10 nanometers thick. In another example, the thin silicon layer 350 can be fewer than 30 nanometers thick.

The silicon layer 350 can be exposed to additional heat either during the deposition process or after the deposition process. In some examples, if the silicon layer 350 is exposed to heat during the deposition process it may not be necessary to add an additional step of heating the silicon layer 350 after deposition. Exposing the silicon layer 350 to heat either during or after the silicon layer deposition further couples (adheres, binds or the like) the silicon to the glass layer 300. Binding the silicon layer 350 to the glass layer 300 can form SiO₂—O—Si—Si bonding. The silicon layer 350, in this example, binds with the existing oxygen in the glass layer 300. In this example, the silicon layer 350 is coupled to the glass layer 300 to form a stable intervening layer.

The silicon layer 350 can be an intervening layer (e.g., adhesion layer) that can be coupled with a metal layer 360. The metal layer 360 can be deposited on the silicon intervening layer with PVD, CVD or ALD, or the like. In an example, the metal layer 360 is deposited on the silicon layer 350 with PVD to form an electrically conductive surface. The metal layer 360 can be deposited on any surface 312, 314, 322 where the silicon layer 350 has been formed. For example, the metal layer 360 can be coupled to the inner surface 322 of the through hole 310 proximate to the first major surface 312 and the second major surface 314. The metal layer 360 can be further adhered to the silicon layer 350 by exposing the metal layer 360 to heat. The deposition of the metal layer can be performed in an inert environment. The thermal anneal can chemically react the silicon layer with the metal later and thereby form a metal-silicide (MₓSi) such as copper silicide (Cu₃Si or composition variants) at the metal-to-glass interface. The metal layer can be any metal, such as copper, cobalt, rhodium, aluminum, gold, silver, palladium or the like.

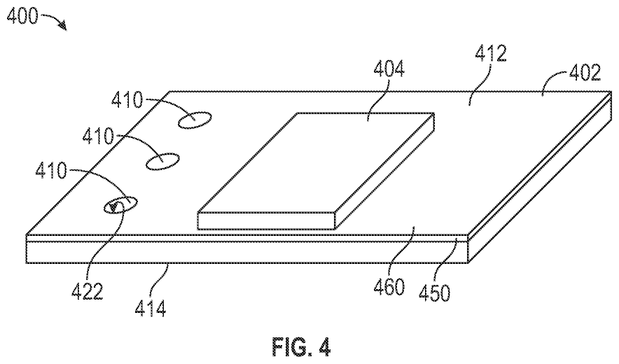

Illustrated in FIG. 4 is an example of a system 400 including a glass layer 402 and a die 404. The glass layer 402 can be any of the layers 100, 200, 300 as previously described. The glass layer 402 can have a first major surface 412 and a second major surface 414 with a plurality of through holes 410 extending between the first major surface 412 and the second major surface 414. In an example, at least one of the surfaces 412, 414, 422 can have a metal layer 460 coupled via an intervening layer 450. The die 404 can be coupled with a surface of the glass layer 402, such as on the metal layer 460, or proximate to the metal layer 460. The die 404 can also be coupled with at least one through hole within the glass layer 402.

While a single die is illustrated in FIG. 4, subsequent layers can be coupled to either of the first major surface 412 or the second major surface 414. For example, a plurality of glass layers 402 can be stacked on each other. The glass layer 402 can also be coupled with a substrate or other package used in a computer system. In another example, the glass layer 402 is indirectly coupled with a die where the die is coupled with a subsequent layer that could comprise of build-up dielectric layer and first level interconnect (FLI) layer on either or both sides of glass layer 402.

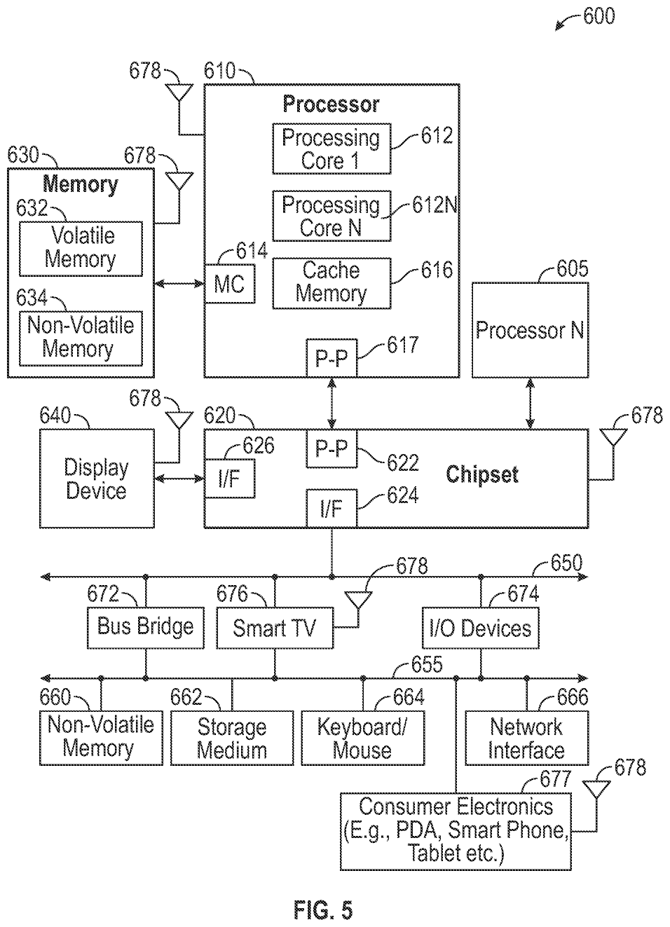

FIG. 5 illustrates a system level diagram, depicting an example of an electronic device (e.g., system) that may include an electronic system, for example, from any of the example process flows described above. In one embodiment, system 600 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 600 includes a system on a chip (SOC) system.

In one embodiment, processor 610 has one or more processor cores 612 and 612N, where 612N represents the Nth processor core inside processor 610 where N is a positive integer. In one embodiment, system 600 includes multiple processors including 610 and 605, where processor 605 has logic similar or identical to the logic of processor 610. In some embodiments, processing core 612 includes, but is not limited to, pre-fetch logic to fetch instructions, decode logic to decode the instructions, execution logic to execute instructions and the like. In some embodiments, processor 610 has a cache memory 616 to cache instructions and/or data for system 600. Cache memory 616 may be organized into a hierarchal structure including one or more levels of cache memory.

In some embodiments, processor 610 includes a memory controller 614, that is operable to perform functions that enable the processor 610 to access and communicate with memory 630 that includes a volatile memory 632 and/or a non-volatile memory 634. In some embodiments, processor 610 is coupled with memory 630 and chipset 620. Processor 610 may also be coupled to a wireless antenna 678 to communicate with any device configured to transmit and/or receive wireless signals. In one embodiment, an interface for wireless antenna 678 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 632 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 634 includes, but is not limited to, flash memory, phase change memory (PCM), read-only memory (ROM), electrically erasable programmable read-only memory (EEPROM), or any other type of non-volatile memory device.

Memory 630 stores information and instructions to be executed by processor 610. In one embodiment, memory 630 may also store temporary variables or other intermediate information while processor 610 is executing instructions. In the illustrated embodiment, chipset 620 connects with processor 610 via Point-to-Point (PtP or P-P) interfaces 617 and 622. Chipset 620 enables processor 610 to connect to other elements in system 600. In some embodiments of the example system, interfaces 617 and 622 operate in accordance with a PtP communication protocol such as the Intel® QuickPath Interconnect (QPI) or the like. In other embodiments, a different interconnect may be used.

In some embodiments, chipset 620 is operable to communicate with processor 610, 605N, display device 640, and other devices, including a bus bridge 672, a smart TV 676, I/O devices 674, nonvolatile memory 660, a storage medium (such as one or more mass storage devices) 662, a keyboard/mouse 664, a network interface 666, and various forms of consumer electronics 677 (such as a PDA, smart phone, tablet etc.), etc. In one embodiment, chipset 620 couples with these devices through an interface 624. Chipset 620 may also be coupled to a wireless antenna 678 to communicate with any device configured to transmit and/or receive wireless signals. In one example, any combination of components in a chipset may be separated by a continuous flexible shield as described in the present disclosure.

Chipset 620 connects to display device 640 via interface 626. Display 640 may be, for example, a liquid crystal display (LCD), a light emitting diode (LED) array, an organic light emitting diode (OLED) array, or any other form of visual display device. In some embodiments of the example system, processor 610 and chipset 620 are merged into a single SOC. In addition, chipset 620 connects to one or more buses 650 and 655 that interconnect various system elements, such as I/O devices 674, nonvolatile memory 660, storage medium 662, a keyboard/mouse 664, and network interface 666. Buses 650 and 655 may be interconnected together via a bus bridge 672.

In one embodiment, mass storage device 662 includes, but is not limited to, a solid state drive, a hard disk drive, a universal serial bus flash memory drive, or any other form of computer data storage medium. In one embodiment, network interface 666 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 5 are depicted as separate blocks within the system 600, the functions performed by some of these blocks may be integrated within a single semiconductor circuit or may be implemented using two or more separate integrated circuits. For example, although cache memory 616 is depicted as a separate block within processor 610, cache memory 616 (or selected aspects of 616) can be incorporated into processor core 612.

### Various Notes and Aspects

Aspect 1 can include semiconductor substrate comprising a glass layer having a first major surface and a second major surface, the second major surface on an opposing side of the glass layer from the first major surface, an electrical transmission through hole extending from the first major surface to the second major surface, and an intervening layer coupled with at least one of the first major surface, the second major surface and the electrical transmission through hole, where the intervening layer includes a metal, silicon and oxygen. The semiconductor substrate also includes a metal layer coupled with the intervening layer.

Aspect 2 can include, or can optionally be combined with the subject matter of Aspect 1, to optionally include the adhesion layer includes titanium, silicon and oxygen.

Aspect 3 can include, or can optionally be combined with the subject matter of Aspect 1 or Aspect 2, to optionally include the metal layer includes copper.

Aspect 4 can include, or can optionally be combined with the subject matter of Aspects 1-3, to optionally include the adhesion layer is a substantially amorphous titanium silicate coupled on an inner surface of the electrical transmission through hole.

Aspect 5 can include, or can optionally be combined with the subject matter of Aspects 1-4, to optionally include the adhesion layer is titanium where the adhesion layer includes a gradient of silicon in the adhesion layer.

Aspect 6 can include, or can optionally be combined with the subject matter of Aspects 1-5, to optionally include the adhesion layer includes silicon.

Aspect 7 can include, or can optionally be combined with the subject matter of Aspects 1-6, to optionally include the adhesion layer is fewer than 30 nanometers thick.

Aspect 8 can include, an electrical system including a semiconductor substrate layer, the semiconductor substrate layer comprising: a glass layer including a first major surface and a second major surface opposite the first major surface, and a through hole having an inner surface and extending between the first major surface and the second major surface. The glass layer including: a conductive metal coupled with at least one of the first major surface, the second major surface or the inner surface of the through hole of the glass layer where the conductive metal extends from proximate to the first major surface to proximate to the second major surface; an intervening layer located at an interface between the conductive metal layer and the glass layer, the intervening layer chemically bonded with the inner surface of the through hole. The electrical system comprises a die coupled to one of the first major surface or the second major surface.

Aspect 9 can include, or can optionally be combined with the subject matter of Aspect 8, to optionally include the intervening layer includes silicon.

Aspect 10 can include, or can optionally be combined with the subject matter of Aspects 8 or Aspect 9, to optionally include the intervening layer is between 5 nanometers and 20 nanometers thick.

Aspect 11 can include, or can optionally be combined with the subject matter of Aspects 8-10, to optionally include the intervening layer is titanium silicate or copper silicide.

Aspect 12 can include, or can optionally be combined with the subject matter of Aspects 8-11, to optionally include the adhesion layer includes at least one of titanium, silicon and oxygen.

Aspect 13 can include, or can optionally be combined with the subject matter of Aspects 8-12, to optionally include the conductive metal includes copper.

Aspect 14 can include, or can optionally be combined with the subject matter of Aspects 8-13, to optionally include the adhesion layer is located on at least one of the first major surface and the second major surface.

Aspect 15 can include, a method of forming a semiconductor substrate layer comprising forming a plurality of through holes in a glass layer and each of the plurality of through holes has an inner surface. Forming an intervening layer on at least the inner surface of at least one of the plurality of through holes. The intervening layer includes metal, silicon and oxygen. Depositing a metal on at least the intervening layer within at least one of the plurality of through holes.

Aspect 16 can include, or can optionally be combined with the subject matter of Aspect 15, to optionally include forming the metal of the metal silicate includes depositing the adhesion layer with at least one of chemical vapor deposition, atomic layer deposition, and physical vapor deposition.

Aspect 17 can include, or can optionally be combined with the subject matter of Aspects 15-16, to optionally include depositing the metal of the metal, silicon and oxygen with one of chemical vapor deposition, atomic layer deposition, or physical vapor deposition and where the metal of the metal, silicon and oxygen reacts with the silicon in the glass of the glass layer in an inert environment.

Aspect 18 can include, or can optionally be combined with the subject matter of Aspects 15-17, to optionally include the intervening layer includes titanium and the method further comprises subjecting the intervening layer to an annealing process after forming the intervening layer.

Aspect 19 can include, or can optionally be combined with the subject matter of Aspects 15-18, to optionally include the intervening layer includes silicon and titanium and the method further comprises forming the intervening layer with a sputtering process.

Aspect 20 can include, or can optionally be combined with the subject matter of Aspects 15-19, to optionally include forming a plurality of semiconductor substrate layers and stacking each of the plurality of semiconductor substrate layers.

Each of these non-limiting aspects can stand on its own, or can be combined in various permutations or combinations with one or more of the other aspects.

The above description includes references to the accompanying drawings, which form a part of the detailed description. The drawings show, by way of illustration, specific embodiments in which the invention can be practiced. These embodiments are also referred to herein as “aspects” or “examples.” Such aspects or example can include elements in addition to those shown or described. However, the present inventors also contemplate aspects or examples in which only those elements shown or described are provided. Moreover, the present inventors also contemplate aspects or examples using any combination or permutation of those elements shown or described (or one or more features thereof), either with respect to a particular aspects or examples (or one or more features thereof), or with respect to other Aspects (or one or more features thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Geometric terms, such as “parallel”, “perpendicular”, “round”, or “square”, are not intended to require absolute mathematical precision, unless the context indicates otherwise. Instead, such geometric terms allow for variations due to manufacturing or equivalent functions. For example, if an element is described as “round” or “generally round,” a component that is not precisely circular (e.g., one that is slightly oblong or is a many-sided polygon) is still encompassed by this description.

The above description is intended to be illustrative, and not restrictive. For example, the above-described aspects or examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as aspects, examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

The claimed invention is:

1. A semiconductor substrate comprising:
a glass layer having a first major surface and a second major surface, the second major surface on an opposing side of the glass layer from the first major surface;
an electrical transmission through hole extending from the first major surface to the second major surface;
an intervening layer coupled with at least one of the first major surface, the second major surface and the electrical transmission through hole;
wherein the intervening layer includes a metal, silicon and oxygen; and
a metal layer coupled with the intervening layer.

2. The semiconductor substrate of claim 1, wherein the intervening layer includes titanium, silicon and oxygen.

3. The semiconductor substrate of claim 1, wherein the metal layer includes copper.

4. The semiconductor substrate of claim 1, wherein the intervening layer is a substantially amorphous titanium silicate coupled on an inner surface of the electrical transmission through hole.

5. The semiconductor substrate of claim 1, wherein the intervening layer is titanium;
wherein the intervening layer includes a gradient of silicon in the intervening layer.

6. The semiconductor substrate of claim 5, wherein the intervening layer includes silicon.

7. The semiconductor substrate of claim 5, wherein the intervening layer is fewer than 30 nanometers thick.

8. An electrical system including a semiconductor substrate layer, the semiconductor substrate layer comprising:
a glass layer including a first major surface and a second major surface opposite the first major surface, and a through hole having an inner surface and extending between the first major surface and the second major surface, the glass layer including:
a conductive metal coupled with at least one of the first major surface, the second major surface or the inner surface of the through hole of the glass layer;
wherein the conductive metal extends from proximate to the first major surface to proximate to the second major surface; and
an intervening layer located at an interface between the conductive metal layer and the glass layer, the intervening layer chemically bonded with the inner surface of the through hole; and
a die coupled to one of the first major surface or the second major surface.

9. The semiconductor substrate layer of claim 8, wherein the intervening layer includes silicon.

10. The semiconductor substrate layer of claim 8, wherein the intervening layer is between 5 nanometers and 20 nanometers thick.

11. The semiconductor substrate layer of claim 8, wherein the intervening layer is titanium silicate or copper silicide.

12. The semiconductor substrate layer of claim 8, wherein the intervening layer includes at least one of titanium, silicon and oxygen.

13. The semiconductor substrate layer of claim 8, wherein the conductive metal includes copper.

14. The semiconductor substrate layer of claim 8, wherein the intervening layer is located on at least one of the first major surface and the second major surface.

15. A method of forming a semiconductor substrate layer comprising:
forming a plurality of through holes in a glass layer;
wherein each of the plurality of through holes has an inner surface;
forming an intervening layer on at least the inner surface of at least one of the plurality of through holes;
wherein the intervening layer includes metal, silicon and oxygen; and
depositing a metal on at least the intervening layer within at least one of the plurality of through holes.

16. The method of claim 15 further comprising:
forming the intervening layer includes depositing the metal of the metal, silicon and oxygen with at least one of chemical vapor deposition, atomic layer deposition, and physical vapor deposition.

17. The method of claim 15, further comprising:
depositing the metal of the metal, silicon and oxygen with one of chemical vapor deposition, atomic layer deposition, or physical vapor deposition;
wherein the metal of the metal, silicon and oxygen reacts with the silicon in the glass of the glass layer in an inert environment.

18. The method of claim 15, wherein the intervening layer includes titanium, the method further comprising:
subjecting the intervening layer to an annealing process after forming the intervening layer.

19. The method of claim 15, wherein the intervening layer includes silicon and titanium, the method further comprising:
forming the intervening layer with a sputtering process.

20. The method of claim 15, further comprising:
forming a plurality of semiconductor substrate layers; and
stacking each of the plurality of semiconductor substrate layers.
